(19) United States
(12) Patent Application Publication
(10) Pub. No.: US 2025/0234613 A1
(43) Pub. Date: Jul. 17, 2025

(54) GALLIUM NITRIDE POWER DEVICES USING NANOSHEET-TYPED CHANNEL LAYERS

(71) Applicant: Massachusetts Institute of Technology, Cambridge, MA (US)

(72) Inventors: Joseph S. Park, Sudbury, MA (US); Jeffrey Daulton, Belmont, MA (US)

(73) Assignee: Massachusetts Institute of Technology, Cambridge, MA (US)

(21) Appl. No.: 18/941,141

(22) Filed: Nov. 8, 2024

Related U.S. Application Data
(60) Provisional application No. 63/619,905, filed on Jan. 11, 2024.

(51) Int. Cl. H01L 29/20; H01L 29/06; H01L 29/423; H01L 29/66; H01L 29/775; H01L 29/786

(52) U.S. Cl. CPC H10D 62/8503; H10D 30/014; H10D 30/43; H10D 30/6757; H10D 62/10; H10D 62/121; H10D 30/6735

(57) ABSTRACT

Described herein is a wide-band gap material transistor device, comprising: a substrate having first and second fins that are spaced apart and project in an orthogonal direction from a surface of the substrate; and a dielectric layer disposed over the surface of the substrate. In some embodiments, the device comprises a channel layer provided from one or more nanosheet heterostructures disposed in the dielectric layer between the first and second fins; and a source and a drain disposed over and in contact with the one or more nanosheet heterostructures and spaced apart from each other in a direction along a length of either the first or the second fins. In some embodiments, the device further comprises a gate, wherein in response to a non-zero voltage applied to the gate, the source and the drain conduct current through a length of the one or more nanosheet heterostructures.

### CROSS REFERENCE TO RELATED APPLICATION

This application claims the benefit under 35 U.S.C. § 119 of U.S. Provisional Patent Application No. 63/619,905 filed on Jan. 11, 2024, which is hereby incorporated herein by reference in its entirety.

### STATEMENT REGARDING FEDERALLY SPONSORED RESEARCH

This invention was made with government support under FA8702-15-D-0001 awarded by the U.S. Air Force. The government has certain rights in the invention.

### BACKGROUND

Higher power densities (e.g., 10 W/mm, the thermal limit of many conventional gallium nitride (GaN) devices) of radio frequency (RF) electronics are called for to deliver high radiated power (e.g., about 10 W (+/−1 W) per unit device for a GaN-on-silicon carbide (SiC) high-electron-mobility transistor (HEMT), which will depend on operation frequencies) in phased arrays. Such arrays entail close spacing between radiating elements at millimeter-wave frequencies to enable high speed communications in both military and commercial applications, such as radar system and 5G cell phones, for example. The RF power density of gallium nitride (GaN) field effect transistors (FETs) have demonstrated the best performances to date. However, such performances have been limited to 7 to 10 W/mm due to technical obstacles, such as high thermal junction-to-packaging resistance (e.g., about 30 K mm/W (+/−1 K mm/W)), epilayer defectivity, and gate leakage current.

### SUMMARY OF DISCLOSED EMBODIMENTS

In one aspect, the present disclosure is directed towards a wide-band gap material transistor device. In some embodiments, the device comprises a substrate having first and second fins that are spaced apart and project in an orthogonal direction from a surface of the substrate. In some embodiments, the device comprises a dielectric layer disposed over the surface of the substrate. In some embodiments, the device comprises a channel layer provided from one or more nanosheet heterostructures disposed in the dielectric layer between the first and second fins. In some embodiments, the device comprises a source and a drain disposed over and in contact with the one or more nanosheet heterostructures and spaced apart from each other in a direction along a length of either the first or the second fins.

In some embodiments, the device further comprises a gate, wherein in response to a non-zero voltage applied to the gate, the source and the drain conduct current through a length of the one or more nanosheet heterostructures. In some embodiments, the dielectric layer is conformally disposed along the first and second fins. In some embodiments, the dielectric layer is conformally disposed along the first and second fins and the dielectric layer has a thickness between 0.01 μm and 0.2 μm. In some embodiments, each one of the one or more nanosheet heterostructures is fully encapsulated by the dielectric layer. In some embodiments, the first fin has a height, a width, and a length that is different than a height, a width, and a length of the second fin. In some embodiments, a height of either one of the first and second fins is between 0.5 μm and 3 μm, a width of either one of the first and second fins is between 0.5 μm and 1.5 μm, and a length of either one of the first and second fins is between 1 μm and 10 μm. In some embodiments, the first fin and the second fin are spaced apart by a distance between 0.5 μm and 5 μm.

In some embodiments, a first nanosheet heterostructure has a height, a width, and a length that is different than a height, a width, and a length of a second nanosheet heterostructure. In some embodiments, a height of the one or more nanosheet heterostructures is between 0.1 μm and 0.3 μm, a width of the one or more nanosheet heterostructures is between 0.45 μm and 0.49 μm, and a length of the one or more nanosheet heterostructures is between 1 μm and 10 μm. In some embodiments, the dielectric layer is GaN doped with a p-type dopant. In some embodiments, the one or more nanosheet heterostructures comprise GaN doped with an n-type dopant. In some embodiments, the substrate is doped with a p-type dopant or an n-type dopant.

According to a further aspect of the disclosure, a method of forming a wide-band gap material transistor device comprises, providing a substrate. In some embodiments, the method comprises disposing one or more buffer layers on the substrate. In some embodiments, the method comprises disposing one or more substrate layers on the one or more buffer layers, wherein the one or more substrate layers includes first and second fins that are spaced apart and project in an orthogonal direction from a surface of the one or more substrate layers. In some embodiments, the method comprises disposing a dielectric layer on the surface of the one or more substrate layers. In some embodiments, the method comprises disposing a channel layer in the dielectric layer between the first and second fins, wherein the channel layer is provided from one or more nanosheet heterostructures. In some embodiments, the method comprises disposing a source and a drain over and in contact with the one or more nanosheet heterostructures and spaced apart from each other in a direction along a length of either of the first and the second fins.

In some embodiments, the method further comprises disposing a gate, wherein in response to applying a non-zero voltage to the gate, the source and the drain conduct current through a length of the one or more nanosheet heterostructures. In some embodiments, disposing the dielectric layer further comprising disposing the dielectric layer conformally along the first and second fins. In some embodiments, the method comprises disposing the dielectric layer further comprising disposing the dielectric layer conformally along the first and second fins and fully encapsulating each one of the one or more nanosheet heterostructures in the dielectric layer. In some embodiments, disposing the dielectric layer further comprising disposing the dielectric layer conformally along the first and second fins and the dielectric layer is GaN doped with a p-type dopant. In some embodiments, the one or more nanosheet heterostructures comprise GaN doped with an n-type dopant. In some embodiments, the method further comprises depositing a passivation layer on the dielectric layer, wherein the passivation layer comprises GaN doped with a p-type dopant.

### DESCRIPTION OF THE SEVERAL VIEWS OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, embodiments are illustrated by way of example and not limitation in the figures, in which:

FIG. 1A is a cross-sectional side view of a conventional gallium nitride (GaN) field effect transistor (FET);

FIG. 1B is a cross-sectional side view of an alternative conventional GaN FET;

FIG. 2 is a cross-sectional side view of a wide-band gap material transistor device;

FIG. 3A is a cross-sectional perspective view of a wide-band gap material transistor device, in accordance with the concepts described herein illustrating current flow;

FIG. 3B is a cross-sectional perspective view of a wide-band gap material transistor device including first and second fins, illustrating current flow;

FIG. 4A is a cross-sectional side view of a wide-band gap material transistor devices including first and second fins, with the voltage turned off illustrating current flow;

FIG. 4B is a cross-sectional side view of a wide-band gap material transistor devices including first and second fins, with the voltage turned on illustrating current flow;

FIG. 4C is a cross-sectional top view of a wide-band gap material transistor device;

FIG. 5 is a flow diagram of an example process for forming a wide-band gap material transistor device;

FIGS. 6A-6H are a series of cross-sectional side views of an example of a wide-band gap material transistor device during fabrication;

FIGS. 7A-7C are a series of cross-sectional side views of an example of a wide-band gap material transistor device with one nanosheet heterostructure during fabrication;

FIGS. 8A-8C are a series of cross-sectional side views of an example of a wide-band gap material transistor device with two nanosheet heterostructures during fabrication; and

FIG. 9 is a graph of drain current (A/mm) and gₘ (S/mm) vs. gate voltage (V).

### DETAILED DESCRIPTION

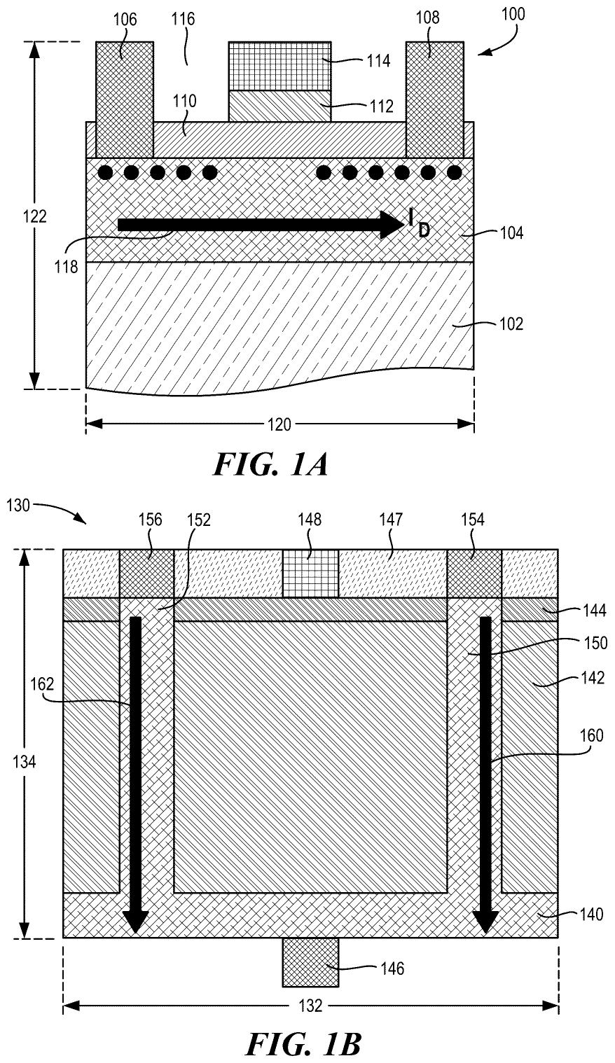

Before describing the broad concepts, devices, systems and techniques sought to be protected herein, some introductory concepts are explained. FIG. 1A is a cross-sectional side view of a conventional gallium nitride (GaN) field effect transistor (FET) 100. A GaN layer 104 is disposed over (here directly on) a substrate 102, with a layer of aluminum gallium nitride (AlGaN) 110 disposed over (here directly on) the GaN layer 104 along a width 122 of the GaN FET 100. A passivation layer 116 is disposed over (here directly on) the AlGaN layer 110. A layer GaN doped with a p-type dopant 112 (herein, a layer of GaN doped with a p-type dopant may generally be referred to herein as “pGaN” or a “pGaN layer”) is disposed over (here directly on) a portion of the AlGaN layer 110 in the passivation layer 116. A gate 114 is disposed over (here directly on) the layer of GaN doped with a p-type dopant 112 in the passivation layer 116. A source 106 is disposed opposite a drain 108 on the AlGaN layer 110 in the passivation layer 116 along a length 120 of the GaN FET 100. In response to a non-zero voltage applied at the gate 114, the source 106 and drain 108 conduct current, as illustrated by arrow 118.

FIG. 1B is a cross-sectional side view of an alternative conventional GaN FET 130. One or more channels 150, 152 project in an orthogonal direction along a width 134 from a surface of a layer of GaN doped with an n-type dopant 140 (herein, a layer of GaN doped with an n-type dopant may generally be referred to herein as “NGaN” or an “NGaN layer”), with a first channel 150 spaced apart from a second channel 152 along a length 132 of the GaN FET 130. The channels 150, 152 are formed from GaN doped with an n-type dopant. A layer of GaN doped with a p-type dopant 142 is disposed over (here directly on) the layer of GaN doped with an n-type dopant 140 and the channels 150, 152. A layer of GaN doped with a P++ type dopant 144 (herein, layer of GaN doped with a P++ type dopant may be referred to as “P++ GaN” or as a “P++ GaN layer”) is disposed over (here directly on) the layer of GaN doped with a p-type dopant 142, but is not disposed over (or here directly on) the channels 150, 152. A passivation layer 147 is disposed over (here directly on) the layer of GaN doped with a P++ type dopant 144.

A gate 148 is disposed over (here directly on) the layer of GaN doped with a P++ type dopant 144. A first source 154 and a second source 156 are disposed over (here directly on) the first and second channels 150, 152, respectively. A drain 146 is disposed over (here directly on) the layer of GaN doped with an n-type dopant 140. In response to a non-zero voltage applied at the gate 148, the sources 154, 156 and drain 146 conduct current, as illustrated by a first arrow 160 and a second arrow 162. The conventional GaN FET 100 and the alternative conventional GaN FET 130 may be operated in enhancement mode (which may be referred to herein as “E-mode”).

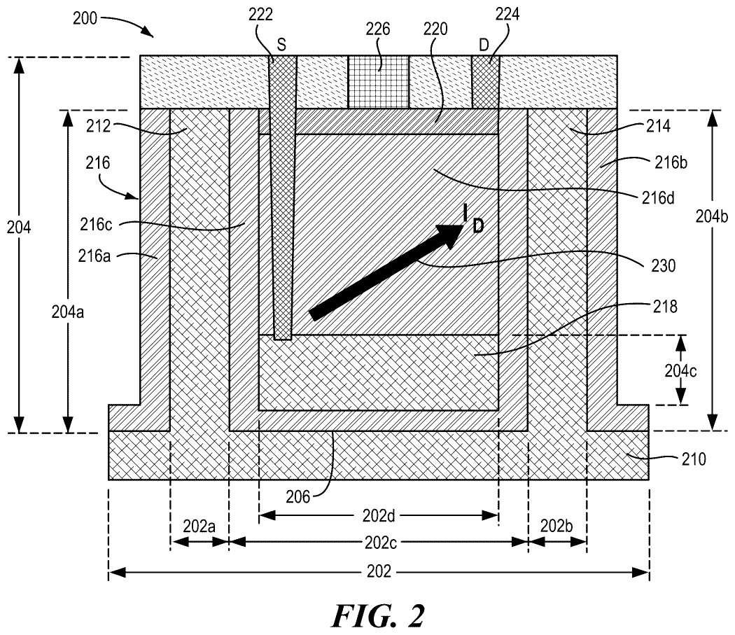

FIG. 2 is a cross-sectional side view of a wide-band gap material transistor device 200 in accordance with the concepts described herein, including one or more fins 212, 214 that are spaced apart and project in an orthogonal direction from a surface 206 of a substrate 210. A first fin 212 is spaced apart along a width 202 of the device 200 from the second fin 214, the fins 212, 214 project in an orthogonal direction along a height 204 of the device 200. A dielectric layer 216a, 216b, 216c (which may be referred to generally as the dielectric layer 216) is disposed over the surface 206 of the substrate 210. A channel layer provided from one or more nanosheet heterostructures, here one nanosheet heterostructure 218 (which may be referred to herein as a nanosheet or as a nanosheet channel layer) is disposed in the dielectric layer 216 between the first and second fins 212, 214. A source 222 and a drain 224 are disposed over and in contact with the nanosheet heterostructure 218 and spaced apart from each other in a direction along a length of either the first or the second fins 212, 214. In response to a non-zero voltage applied to the gate 226, the source 222 and the drain 224 conduct current through a length of the nanosheet heterostructure 218, as illustrated by arrow 230.

The substrate 210 is formed from one or more layers of undoped GaN. In an embodiment, the substrate 210 is doped with a p-type dopant or an n-type dopant. Wide band gap refers to a material the device 200 is formed from (wide meaning a material with a band gap greater than 2 eV). The wide band gap material may comprise one or more of: gallium nitride (GaN), aluminum gallium nitride (AlₓGa_{y}N, x+y=1), aluminum nitride (AlN), boron aluminum nitride (BₓA_{y}IN, x+y=1), gallium oxide (Ga₂O₃), silicon carbide (SiC), diamond, or boron nitride (BN).

The fins 212, 214 are formed form one or more layers of undoped GaN. In embodiments, the first fin 212 has a height 204a, a width 202a, and a length that is different than a height 204b, a width 202b, and a length of the second fin 214. In embodiments, the fins 212, 214, have the same height, width, and length.

The dielectric layer 216 may be GaN doped with a p-type dopant. The dielectric layer 216a, 216b, 216c is disposed conformally along the first fin 212, the second fin 214, and the substrate 210. A first dielectric layer portion 216a is disposed over (here directly on) the substrate 210 and the first fin 212. A second dielectric layer portion 216b is disposed over (here directly on) the substrate 210 and the second fin 214. A third dielectric layer portion 216c is disposed over (here directly on) the first fin 212, the substrate 210, and the second fin 214.

A dielectric layer portion 216d is disposed over (here directly on) the nanosheet heterostructure 218 and the dielectric layer portion 216c. The dielectric layer portion 216d may be GaN doped with a p-type dopant. Thus, the nanosheet heterostructure is fully encapsulated by the dielectric layer 216c, 216d. A p++ GaN layer 220 is disposed over (here directly on) the dielectric layer portion 216c. A gate 226 is disposed over (here directly on) the p++ GaN layer 220.

The nanosheet heterostructure 218 has a width 202d, a height 204c, and a length. In one example embodiment for operation in the millimeter wave (MMW) frequency range, the total width 202 of the device 200 may be about 3 um (+/−1 um); the height 204a, 204b of either one of the first and second fins 212, 214 may be between about 0.5 μm (+/−0.1 μm) and about 3 μm (+/−0.1 μm), a width 202a, 202b of either one of the first and second fins 212, 214 may be between about 0.5 μm (+/−0.1 μm) and about 1.5 μm (+/−0.1 μm), and a length of either one of the first and second fins 212, 214 may be between about 1 μm (+/−0.1 μm) and about 10 μm (+/−1 μm). The first fin 212 and the second fin 214 are spaced apart by a distance 202c between about 0.5 μm (+/−0.1 μm) and about 5 μm (+/−0.1 μm); the dielectric layer 216a, 216b, 216c has a thickness between about 0.01 μm (+/−0.001 μm) and about 0.2 μm (+/−0.001 μm); and the height 204c of the one or more nanosheet heterostructure 218 may be between about 0.1 μm (+/−0.01 μm) and about 0.3 μm (+/−0.1 μm), the width 202d of the nanosheet heterostructure 218 may be between about 0.45 μm (+/−0.1 μm) and about 0.49 μm (+/−0.1 μm), and a length of the nanosheet heterostructure 218 may be between about 1 μm (+/−0.1 μm) and about 10 μm (+/−1 μm).

While the wide-band gap material transistor device 200 is shown with one nanosheet heterostructure, multiple nanosheet heterostructures are possible (e.g. two or more nanosheet heterostructures). In an embodiment with two nanosheet heterostructures, a first nanosheet heterostructure has a height, a width, and a length that is different than a height, a width, and a length of a second nanosheet heterostructure. The nanosheet heterostructure 218 can comprise a doped GaN layer. For example, nanosheet heterostructure 218 can comprise GaN doped with an n-type dopant.

The geometry of the fins will vary based on the device fabrication process. Various factors of the fabrication process that may influence the geometry of one or more of the fins include the patterning masks and the etching time of the reactive-ion etching (RIE) process. Specifically, the width or height of one or more of the fins could be controlled via the opening size of the patterning masks and the etching time of the RIE process. Thermal design may call for one or more fins to be scaled in accordance with the size of the device, thus as the device increases in size so may one or more of the fins. Further, an increase in one or more fin sizes, and accordingly device size, may call for an increase in the gap between adjacent stacks of nanosheet heterostructures.

The device scheme disclosed herein comprises so called nanosheet heterostructures, which act as a channel layer and are disposed over (e.g. horizontally placed on) a doped GaN layer. In this example embodiment, the GaN layer is doped with a p-type dopant between neighboring GaN fins, as illustrated in FIG. 2. Thus, in this example, the disclosed wide-band gap material transistor device 200 is a GaN nanosheet FET including a single nGaN nanosheet that is surrounded by pGaN layers.

The pGaN layers enable the device 200 to be operated via normally-off mode at zero gate bias voltage. Compared to conventional enhancement-mode planar GaN FETs and vertical GaN fin-shaped FETs (FinFETs), the disclosed device scheme reduces leakage current and increases drain current, leading to high power densities (e.g., about 100 W/mm (+/−10 W/mm)). A full encapsulation of the nanosheet heterostructure with the dielectric layers and GaN doped with a p-type dopant leads to a reduction in the leakage current. In relation to an embodiment with multiple nanosheet heterostructures, the multiple nanosheet heterostructures further increase the drain current and power density. The channel resistance of multiple nanosheet heterostructures acting as channel layers is reduced by connecting them in parallel, resultingly increasing the drain current. Thus, inclusion of a nanosheet heterostructure as described herein reduces leakage current and increases drain current, thereby leading to high power densities.

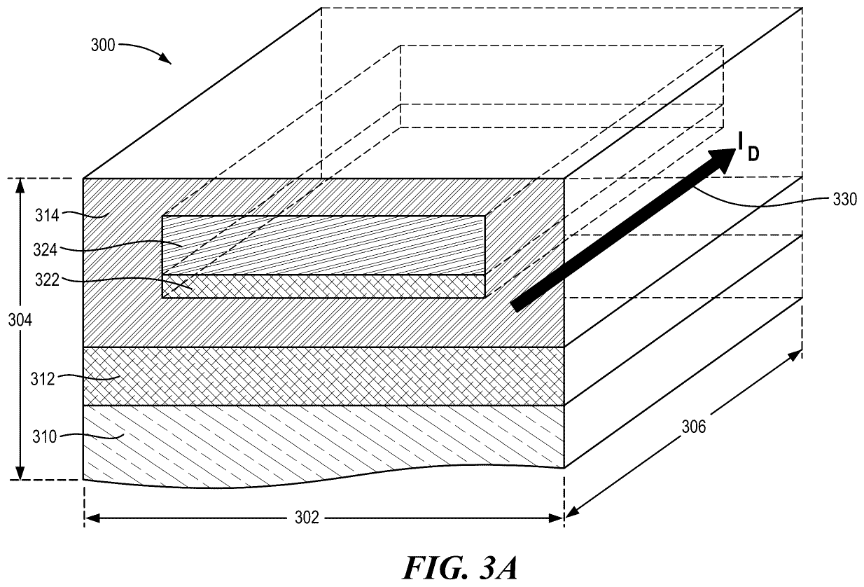

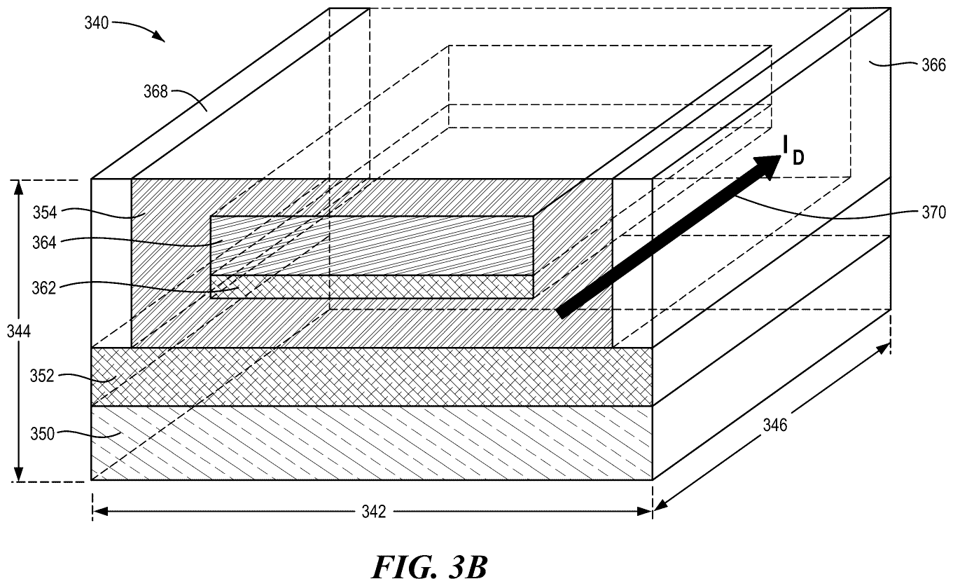

FIG. 3A is a cross-sectional perspective view of a wide-band gap material transistor device 300, illustrating current flow in arrow 330. The device 300 includes a GaN layer 312 disposed over (here directly on) a substrate 310 along a width 302, height 304, and length 306 of the device 300. A dielectric layer 314 is disposed over (here directly on) the GaN layer 312. The dielectric layer 314 as disclosed in FIG. 3A is formed from a GaN layer doped with a P-type dopant. A channel layer is provided from a nanosheet heterostructure 322, which is disposed in the dielectric layer 314. The nanosheet heterostructure 322 is formed from a layer of GaN doped with a N-type dopant. For example, the N-type dopant may be silicon (Si). Additional layers of the dielectric are disposed over (here directly on) the nanosheet heterostructure 322, specifically layer 324 is formed from one or more layers of GaN doped with a P-type dopant with one or more layers of GaN doped with a P++ type dopant disposed on the one or more layers of GaN doped with a P-type dopant. The nanosheet heterostructure 320 conducts current through the length 306 of the device 300. Specifically, the channel formed by the nanosheet heterostructure 320 conducts current via electrons the Si donors. The current flow through the device 300 is illustrated by arrow 330.

FIG. 3B is a cross-sectional perspective view of a wide-band gap material transistor device 340 including first and second fins 366, 368, illustrating current flow in arrow 370. The device 340 includes a GaN layer 352 disposed over (here directly on) a substrate 350 along a width 342, a height 344, and a length 346 of the device 340. A dielectric layer 354 is disposed over (here directly on) the GaN layer 352. The dielectric layer 354 as disclosed in FIG. 3B is formed from a GaN layer doped with a P-type dopant. A first fin 366 is disposed opposite a second fin 368 and spaced apart along the width 342 of the device. The length 346 of the device is additionally the length 346 of the fins 366, 368. A channel layer is provided from a nanosheet heterostructure 362, which is disposed in the dielectric layer 354. The nanosheet heterostructure 362 is formed from a GaN layer doped with an n-type dopant.

Additional layers of the dielectric are disposed over (here directly on) the nanosheet heterostructure 362, specifically layer 364 is formed from one or more GaN layers doped with a P-type dopant with one or more GaN layers doped with a p++ type dopant disposed on the one or more GaN layers doped with a p-type dopant. The nanosheet heterostructure 360 conducts current through the length 346 of the device 340. The current flow through the device 340 is illustrated by arrow 370.

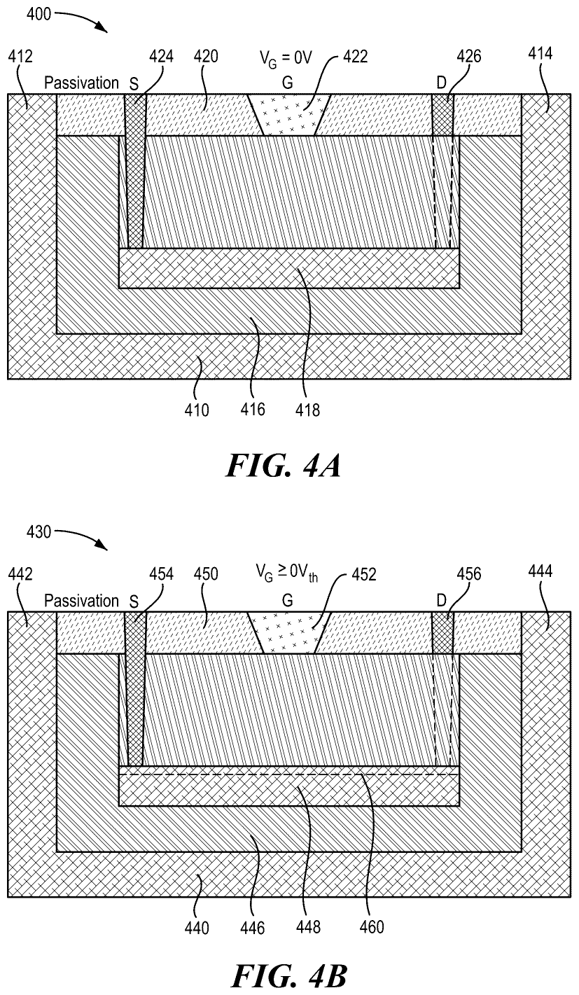

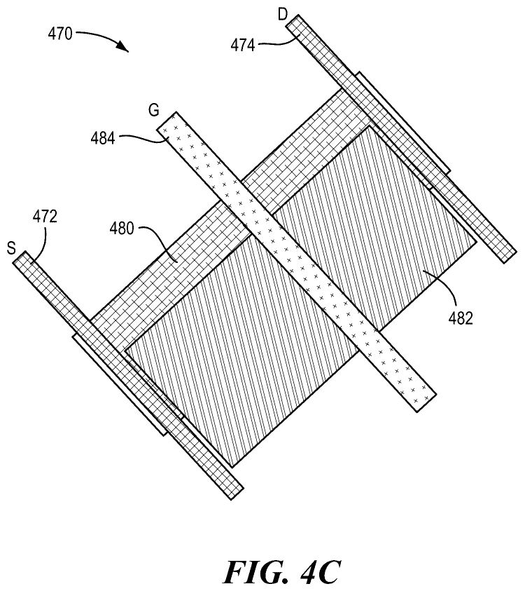

FIG. 4A is a cross-sectional side view of a wide-band gap material transistor device 400 with the voltage turned off, illustrating current flow in the device. In the first device 400, a substrate 410 includes a first fin 412 and a second fin 414 that are spaced apart and project in an orthogonal direction from a surface of the substrate 410. In an embodiment, such as the device 400 of FIG. 4A, the substrate 410 is undoped GaN. A dielectric layer 416 is disposed over the surface of the substrate 410 and the fins 412, 414. A channel layer 418 provided from a nanosheet heterostructure disposed in the dielectric layer 416 between the first and second fins 412, 414. A passivation layer 420 is disposed over (here directly on) the dielectric layer 416.

A gate 422 is disposed in the passivation layer 420, atop the dielectric layer 416. A source 424 is disposed opposite a drain 426 in the dielectric layer 416 and the passivation layer 420, in contact with the channel layer 418. In the first device 400, the voltage at the gate is 0V. Accordingly, the source 424 and the drain 426, and resulting the device 400, do not conduct current.

FIG. 4B is a cross-sectional side view of a wide-band gap material transistor device 430 with the voltage turned on, illustrating current flow in the device. In the second device 430, a substrate 440 includes a first fin 442 and a second fin 444 that are spaced apart and project in an orthogonal direction from a surface of the substrate 440. In an embodiment, such as the device 430 of FIG. 4B the substrate 440 is undoped GaN. A dielectric layer 446 is disposed over the surface of the substrate 440 and the fins 442, 444. A channel layer 448 provided from a nanosheet heterostructure disposed in the dielectric layer 446 between the first and second fins 442, 444. A passivation layer 450 is disposed over (here directly on) the dielectric layer 446.

A gate 452 is disposed in the passivation layer 450, atop the dielectric layer 446. A source 454 is disposed opposite a drain 456 in the dielectric layer 446 and the passivation layer 450, in contact with the channel layer 448. In the second device 430, the voltage at the gate is greater than 0V. Accordingly, the source 454 and the drain 456 conduct current through the channel layer 448, as illustrated by dotted line 460.

FIG. 4C is a top view of a cross-section of a wide-band gap material transistor device 470, including a channel layer 480 provided from a nanosheet heterostructure. A source 472 is disposed opposite a drain 474, with the channel layer 480 disposed between and in contact with the source 472 and drain 474. The channel layer 480 may, for example, include GaN doped with an n-type dopant. A dielectric layer 482 is disposed over (here directly on) the channel layer 480, which may, for example, include GaN doped with a P++ type dopant. A gate 484 is disposed over (here directly on) the dielectric layer 482, between the source 472 and the drain 474.

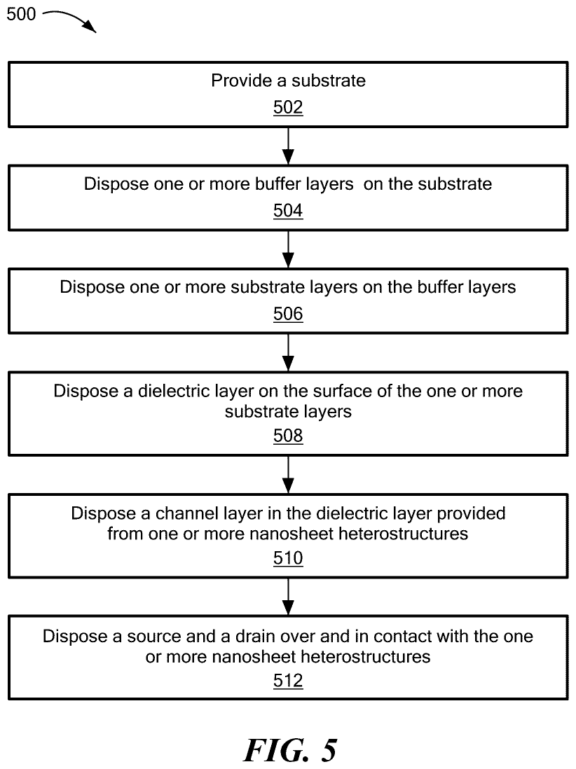

FIG. 5 is a process 500 for forming a wide-band gap material transistor device. The process 500 may be used to form the wide-band gap material transistor device described in conjunction with FIGS. 2-4B.

At block 502, a substrate is provided. At block 504, one or more buffer layers are disposed on the substrate. At block 506, one or more substrate layers are disposed on the buffer layers. In an embodiment, the one or more substrate layers includes first and second fins that are spaced apart and project in an orthogonal direction from a surface of the one or more substrate layers.

At block 508, a dielectric layer is disposed on the surface of the one or more substrate layers. At block 510, a channel layer is disposed in the dielectric layer provided from one or more nanosheet heterostructures. In an embodiment, the channel layer in the dielectric layer is disposed between the first and second fins and the channel layer is provided from one or more nanosheet heterostructures.

At block 512, a source and a drain are disposed over and in contact with the one or more nanosheet heterostructures. In an embodiment, the source and drain are disposed over and in contact with the one or more nanosheet heterostructures and spaced apart from each other in a direction along a length of either of the first and the second fins.

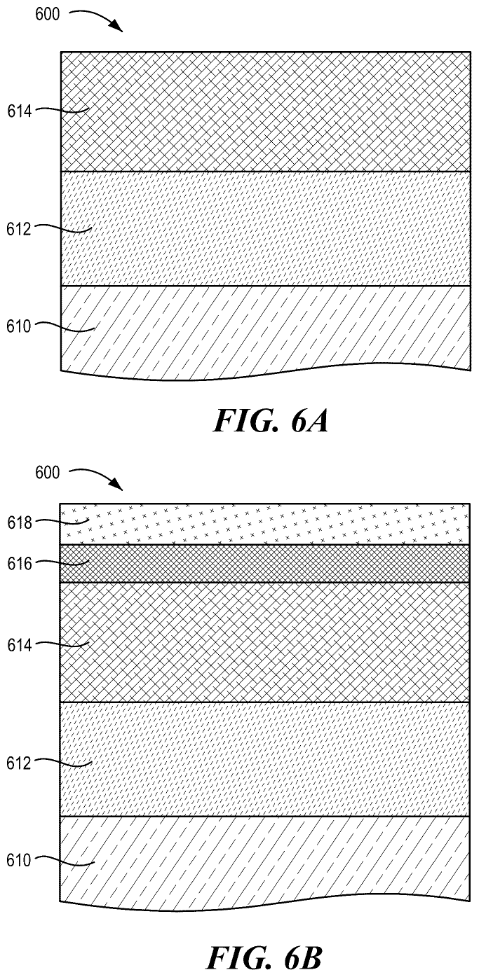

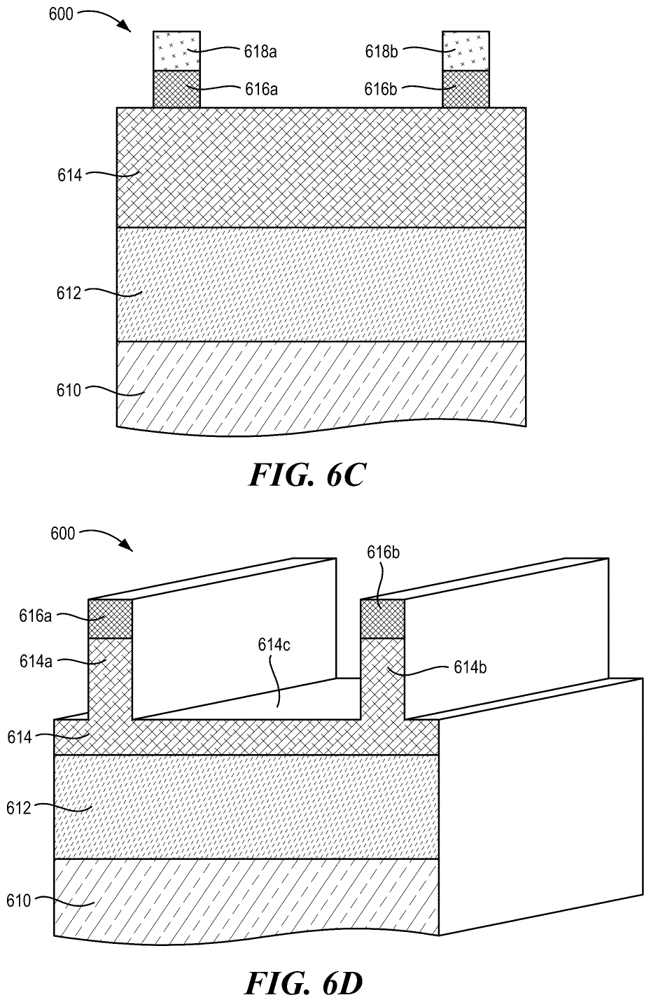

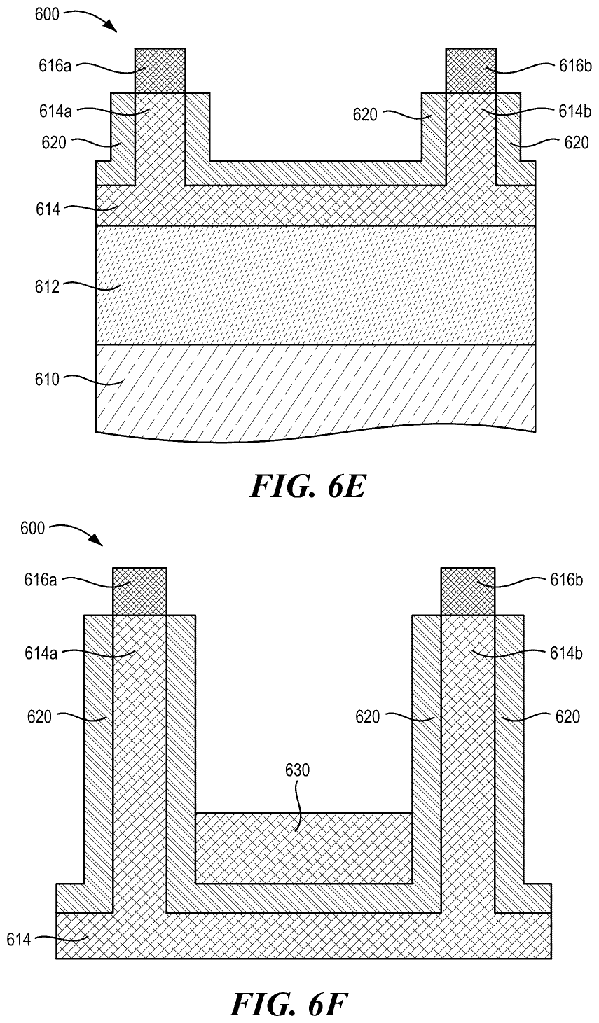

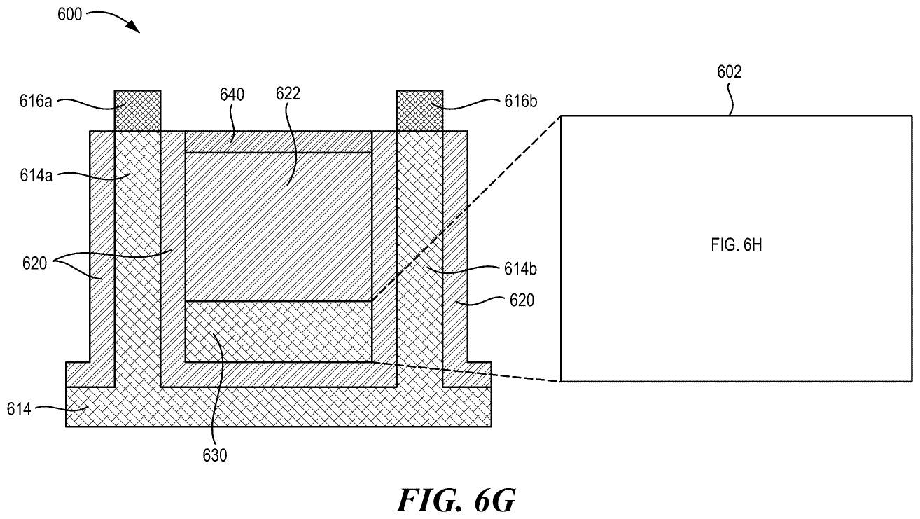

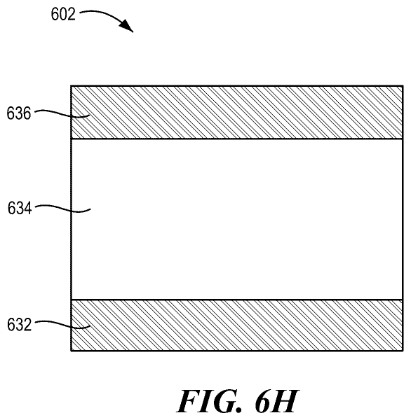

FIGS. 6A-6H are cross-sectional side views of an example of a wide-band gap material transistor device 600 during fabrication, with like numbers representing like parts. The fabrication disclosed in FIGS. 6A-6H may be similar to or the same as the process 500 described in conjunction with FIG. 5. The process disclosed in relation to FIGS. 6A-6H may be used for a wide-band gap material transistor, such as the device 200 disclosed in FIG. 2. FIGS. 6A-6H illustrate an example embodiment of multiple additive and subtractive semiconductor processing techniques which may be used to form the device, however other semiconductor processing techniques may be used.

Referring to FIG. 6A, one or more buffer layers 612 are disposed over (here directly on) a substrate 610. The substrate 610 may be silicon (Si), sapphire, GaN, silicon carbide (SiC), or another engineered substrate. A layer of undoped GaN 614 is disposed over (here directly on) the buffer layers 612. In embodiments, the buffer layer 612 is undoped GaN, AlN and/or AlGaN. The structure of buffer layers 612 will depend on material the substrate 610 is formed from. Undoped GaN layers are conventional buffer layers 612 on Si, SiC, or sapphire GaN substrates 610. While AlN or AlGaN buffer layers could be combined with the undoped GaN buffer layers if needed to form the buffer layers 612. The GaN layer growth is performed by metal-organic chemical vapor deposition (which may be referred to herein as MOCVD) system. In one example embodiment for operation in the MMW frequency range, the thickness of the layer of undoped GaN 614 may be in the range of about 0.5 um (+/−0.1 um) to about 20 um (+/−0.1 um).

Referring now to FIG. 6B, a hard mask layer 616 is disposed over (here directly on) the layer of undoped GaN 614. The hard mask layer 616 may be silicon nitride (Si₃N₄) and may be disposed by a chemical vapor deposition (which may be referred to herein as CVD) systems. The hard mask layer 616 may have a thickness in the range of about 0.2 um (+/−0.1 um) to about 2 um (+/−0.1 um). A photoresist layer 618 is disposed over (here directly on) the hard mask layer 616. The photoresist layer 618 may have a thickness in the range of about 1 um (+/−0.1 um) to about 10 um (+/−1 um). Following, the photoresist layer 618 is patterned, after which the hard mask layer 616 is etched away, leaving two distinct photoresist layer and hard mask layer sections on opposite each other on the device 600.

Referring now to FIG. 6C, a first hard mask layer 616a is disposed over (here directly on) the layer of undoped GaN 614, with a first photoresist layer 618a disposed over (here directly on) the first hard mask layer 616a. A second hard mask layer 616b is disposed over (here directly on) the layer of undoped GaN 614, with a second photoresist layer 618b disposed over (here directly on) the second hard mask layer 616b.

Referring now to FIG. 6D, the layer of undoped GaN 614 is etched away, resulting in the fabrication of first and second fins 614a, 614b. A first fin 614a and a second fin 614b are spaced apart and project in an orthogonal direction from a surface 614c of the layer of undoped GaN 614. The surface 614c region may be referred to as a trench region. The first and second fins 614a, 614b have a height in the range of about 0.5 um (+/−0.1 um) to about 3 um (+/−0.1 um), a width in the range of about 0.05 um (+/−0.01 um) to about 1.0 um (+/−0.1 um), and a length in the range of about 1.0 um (+/−0.1 um) to about 10.0 um (+/−1 um). The distance between the fins 614a, 614b is in the range about 0.5 um (+/−0.1 um) to about 5 um (+/−1 um). The first hard mask layer 616a resides on the first fin 614a and the second hard mask layer 616b resides on the second fin 614b. Additionally, the first and second photoresist layers 618a, 618b are removed.

Referring now to FIG. 6E, a dielectric layer 620 is conformally disposed over (here directly on) the surface 614c of the layer of undoped GaN 614 and the first and second fins 614a, 614b. The dielectric layer 620 can be GaN doped with a p-type dopant, the Mg doping concentration may be in the range of about 1e¹⁹ cm⁻³ to about 9e¹⁹ cm⁻³ (+/−1e¹⁹ cm⁻³) and the net doping concentration after the pGaN activation may be in the range of about 1e¹⁷ cm⁻³ to 9e¹⁷ cm⁻³ (+/−1e¹⁷ cm⁻³). The dielectric layer 620 is conformally grown along the fins 614a, 5614b and surface 614c by MOCVD. The thickness of the dielectric layer 620 may be in the range of about 0.01 um (+/−0.001 um) to about 0.2 um (+/−0.01 um), the dielectric layer 620 in FIG. 6E may be about 0.1 um (+/−0.01 um) thick.

Referring now to FIG. 6F, a channel layer 630 is disposed over (here directly on) the dielectric layer 620. The channel layer 630 may be formed from a nanosheet heterostructure. The channel layer 630 is conformally grown by MOCVD. The channel layer 630 can be GaN doped with an n-type dopant, with a net doping concentration in the range of about 1e¹⁷ cm⁻³ (+/−1e¹⁷ cm⁻³) to about 3e¹⁷ cm⁻³ (+/−1e¹⁷ cm⁻³). The channel layer 630 has a thickness between about 0.01 um (+/−0.001 um) to about 0.3 um (+/−0.1 um), a width between about 0.45 um (+/−0.1 um) to about 4.9 um (+/−1 um), and a length between about 1 um (+/−0.1 um) to about 10 um (+/−1 um).

Referring now to FIG. 6G, additional layer of dielectric 622 is disposed atop the channel layer 630. The additional layer of dielectric 622 is conformally grown by MOCVD. The additional layer of dielectric 622 include one or more layers of GaN doped with a p-type dopant, the one or more layers of GaN doped with a p-type dopant have a thickness between about 0.1 um (+/−0.01 um) to about 0.3 um (+/−0.1 um) and have the same Mg doping concentration ranges as the dielectric layer 620, specifically the Mg doping concentration in the range of about 1e¹⁹ cm⁻³ (+/−1e¹⁹ cm⁻³) to about 9e¹⁹ cm⁻³ (+/−1e¹⁹ cm⁻³) and the net doping concentration after the pGaN activation is in the range of about 1e¹⁷ cm⁻³ (+/−1e¹⁷ cm⁻³) to about 9e¹⁷ cm⁻³ (+/−1e¹⁷ cm⁻³ ). A layer of GaN doped with a P++ dopant 640 is disposed over (here directly on) the additional layer of dielectric 622 between the first and second fins 614a, 614b. The layer of GaN doped with a P++ dopant 640 have a thickness between about 0.05 um (+/−0.001 um) to about 0.1 um (+/−0.1 um) and have a Mg doping concentration is in the range of about 1e²⁰ cm⁻³ (+/−1e²⁰ cm⁻³) to about 1e²¹ cm⁻³ (+/−1e²⁰ cm⁻³).

Resultingly, FIG. 6G illustrates the formation of a lateral p-n junction at zero gate bias, as illustrated in FIG. 6H in portion 602. A depletion region 634 is disposed atop a first dielectric layer 632, with a second dielectric layer 626 disposed atop the depletion region 634.

The channel layer 630 formed from GaN doped with an n-type dopant is encapsulated with the dielectric layers 620, 622 formed from pGaN layers. Resultingly, a p-n junction is generated inside the nGaN channel layer region. The p-n junction region can be fully depleted by modulating the doping concentration of both nGaN and pGaN layers, resulting in a “normally-off” device state at zero gate bias voltage condition. The source, gate, and drain contact metal stacks are deposited on the nGaN nanosheet and p++ GaN layer (as illustrated by FIGS. 2-5). The source and drain contacts are placed on both sides of the nGaN nanosheet. This normally-off GaN nanosheet FET is turned on as the gate bias voltage becomes higher than a threshold voltage.

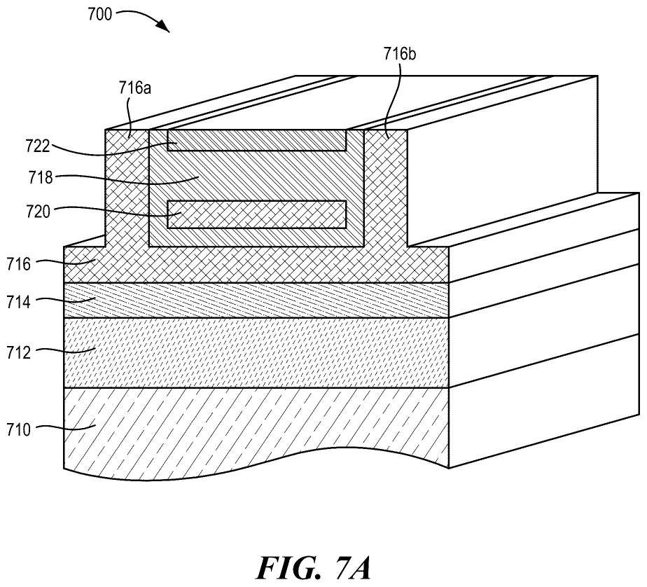

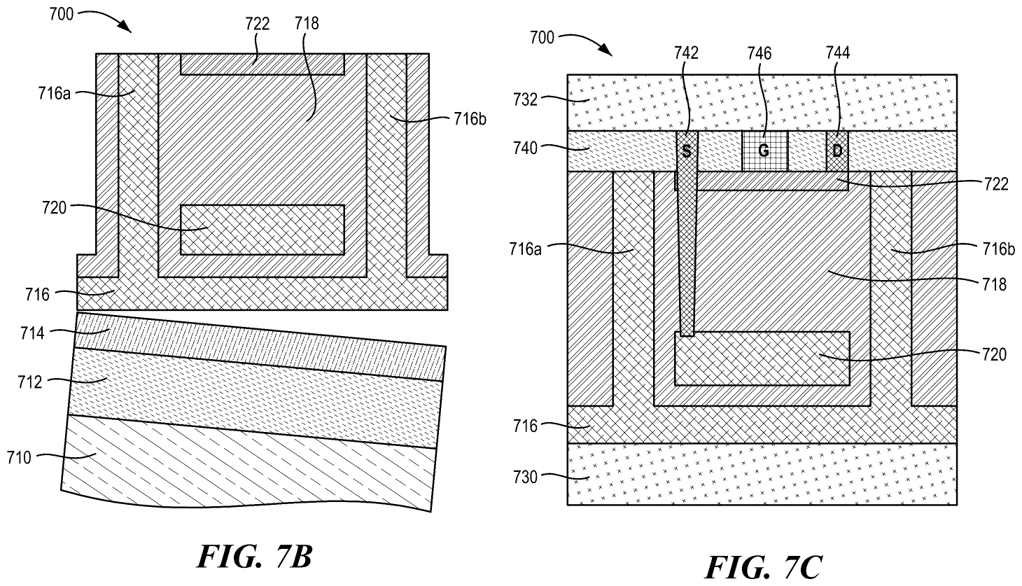

FIGS. 7A-7C are cross-sectional side views of an example of a wide-band gap material transistor device 700 with one nanosheet heterostructure during fabrication, with like numbers representing like parts. The process disclosed in relation to FIGS. 7A-7C may be used for a wide-band gap material transistor, such as the device 200 disclosed in FIG. 2. The process may be used to form the device following the process described in relation to the wide-band gap material transistor device 600 in FIGS. 6A-6H. FIGS. 7A-7C illustrate an example embodiment of multiple additive and subtractive semiconductor processing techniques which may be used to form the device, however other semiconductor processing techniques may be used.

FIG. 7A illustrates one example of the fabrication (e.g., growth) of a single nanosheet heterostructure 720 between two fins 716a, 716b. One or more buffer layers 712 are disposed over (here directly on) a substrate 710. A release layer 714 is disposed over (here directly on) the buffer layers 712. The release layer 714 may be layer of indium gallium nitride (InGaN) that is 100 nm thick. A layer of undoped GaN 716 is disposed over (here directly on) the buffer layers 712. A first fin 716a and a second fin 716b are spaced apart and project in an orthogonal direction from a surface of the layer of undoped GaN 716.

A dielectric layer 718 is disposed over (here directly on) the layer of undoped GaN 716 and the first and second fins 716a, 716b. The dielectric layer 718 may be a layer of GaN doped with a p-type dopant. A the layer of GaN doped a with P++ type dopant 722 is disposed over (here directly on) the dielectric layer 718 between the first and second fins 716a, 716b. A channel is formed from the nanosheet heterostructure 720 and is disposed in the dielectric layer 718. The nanosheet heterostructure 720 can be GaN doped with an n-type dopant.

FIG. 7B illustrates the chemical lift off (CLO) of the layer of undoped GaN 716, fins 716a, 716b, dielectric layer 718, nanosheet heterostructure 720, and layer of GaN doped a with P++ type dopant 722 from the substrate. In FIG. 7B, the layer of undoped GaN 716, fins 716a, 716b, dielectric layer 718, nanosheet heterostructure 720, and layer of GaN doped a with P++ type dopant 722 are lifted off from the release layer 714, buffer layers 712, and substrate 710. Following the CLO disclosed in FIG. 7B, the GaN layers are chemically separated from the substrate. FIG. 7B is an example embodiment to illustrate the CLO, wherein the release layer 714, the buffer layers 712, and the substrate 710 are partially removed. In practice, the release layer 714, the buffer layers 712, and the substrate 710 are fully removed.

FIG. 7C illustrates double sided bonding of the nanosheet FETs to diamond substrates. Specifically, the layer of undoped GaN 716, fins 716a, 716b, dielectric layer 718, nanosheet heterostructure 720, and layer of GaN doped a with P++ type dopant 722 are bonded to substrates 730, 732. In the embodiment illustrated in FIG. 7C, the substrates 730, 732 are diamond wafers. Following the CLO disclosed in FIG. 7B, the contact metal is deposited and the GaN layers are bonded to diamond wafers for improved thermal dissipation.

The layer of undoped GaN 716 is bonded to a first substrate 730. A passivation layer 740 is disposed over (here directly on) the fins 716a, 716b, dielectric layer 718, and the layer of GaN doped a with P++ type dopant 722. A source 742 and a drain 744 are disposed in the passivation layer 740 and the passivation layer 740 on either side of the device 700 and in contact with the nanosheet heterostructure 720. A gate 746 is disposed in the passivation layer 740 on the layer of GaN doped a with P++ type dopant 722 between the source 742 and the drain 744. A second substrate 732 is disposed over (here directly on) the passivation layer 740, the source 742, drain 744, and gate 746.

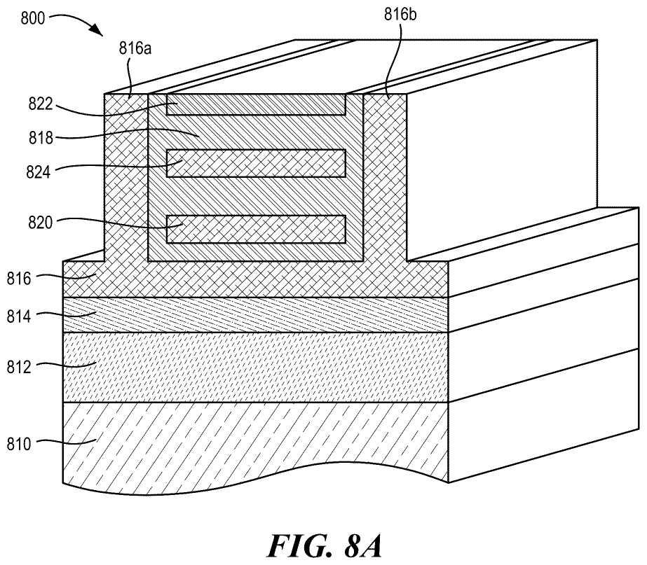

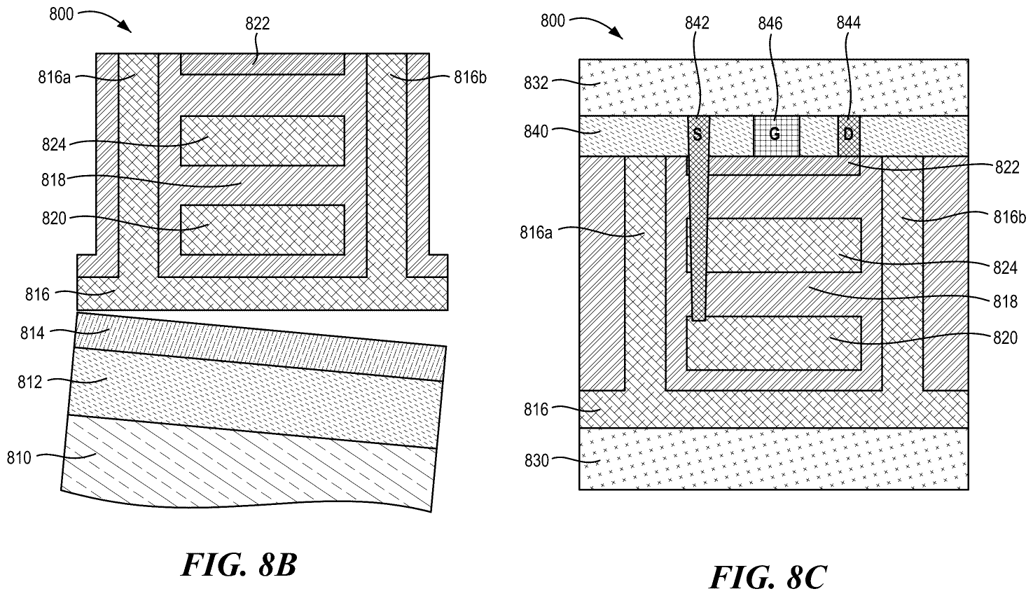

FIGS. 8A-8C are cross-sectional side views of an example of a wide-band gap material transistor device 800 with two nanosheet heterostructures during fabrication, with like numbers representing like parts. For example, the process may be used for a wide-band gap material transistor, which may be similar to the device 200 disclosed in FIG. 2, but would instead include two nanosheet heterostructures. The process may be used to form the device following the process described in relation to the wide-band gap material transistor device 600 in FIGS. 6A-6H. FIGS. 8A-8C illustrate an example embodiment of multiple additive and subtractive semiconductor processing techniques which may be used to form the device, however other semiconductor processing techniques may be used.

FIG. 8A illustrates the growth of a multiple nanosheet heterostructures 820, 824 between two fins 816a, 816b. One or more buffer layers 812 are disposed over (here directly on) a substrate 810. A release layer 814 is disposed over (here directly on) the buffer layers 812. The release layer 814 may be layer of InGaN that is 100 nm thick. A layer of undoped GaN 816 is disposed over (here directly on) the buffer layers 812. A first fin 816a and a second fin 816b are spaced apart and project in an orthogonal direction from a surface of the layer of undoped GaN 816. Disposed over (here directly on) the layer of undoped GaN 816 and the first and second fins 816a, 816b is a dielectric layer 818. The dielectric layer 818 may be a layer of GaN doped with a p-type dopant. A layer of GaN doped a with P++ type dopant 822 is disposed over (here directly on) the dielectric layer 818 between the first and second fins 816a, 816b.

A channel formed from the nanosheet heterostructures 820, 824 and is disposed in the dielectric layer 818. The channel is formed from a first nanosheet heterostructure 820 and a second nanosheet heterostructure 824. The first nanosheet heterostructure 820 is disposed in the dielectric layer 818 over the layer of undoped GaN 816. The second nanosheet heterostructure 824 is disposed in the dielectric layer 818 over the first nanosheet heterostructure 820. The nanosheet heterostructures 820, 824 can be GaN doped with an n-type dopant.

FIG. 8B illustrates the CLO of the layer of undoped GaN 816, fins 816a, 816b, dielectric layer 818, nanosheet heterostructures 820, 824, and layer of GaN doped a with P++ type dopant 822 from the substrate. In FIG. 8B, the layer of undoped GaN 816, fins 816a, 816b, dielectric layer 818, nanosheet heterostructures 820, 824, and layer of GaN doped a with P++ type dopant 822 are lifted off from the release layer 814, buffer layers 812, and substrate 810. Following the CLO disclosed in FIG. 8B, the GaN layers are chemically separated from the substrate. FIG. 8B is an example embodiment to illustrate the CLO, wherein the release layer 814, buffer layers 812, and substrate 810 are partially removed. In practice, the release layer 814, buffer layers 812, and substrate 810 are fully removed.

FIG. 8C illustrates double sided bonding of the nanosheet FETs to diamond substrates. Specifically, the layer of undoped GaN 816, fins 816a, 816b, the dielectric layer 818, the nanosheet heterostructures 820, 824, and the layer of GaN doped a with P++ type dopant 822 are bonded to substrates 830, 832. In the embodiment illustrated in FIG. 8C, the substrates 830, 832 are diamond wafers. Following the CLO disclosed in FIG. 8B, the contact metal is deposited and the GaN layers are bonded to diamond wafers for better thermal dissipation.

The layer of undoped GaN 816 is bonded to a first substrate 830. A passivation layer 840 is disposed over (here directly on) the fins 816a, 816b, dielectric layer 818, and the layer of GaN doped a with p++ type dopant 822. A source 842 and a drain 844 are disposed in the passivation layer 840 and the passivation layer 840 on either side of the device 800 and in contact with the nanosheet heterostructures 820, 824. A gate 846 is disposed in the passivation layer 840 on the layer of GaN doped a with p++ type dopant 822 between the source 842 and the drain 844. A second substrate 832 is disposed over (here directly on) the passivation layer 840, the source 842, drain 844, and gate 846.

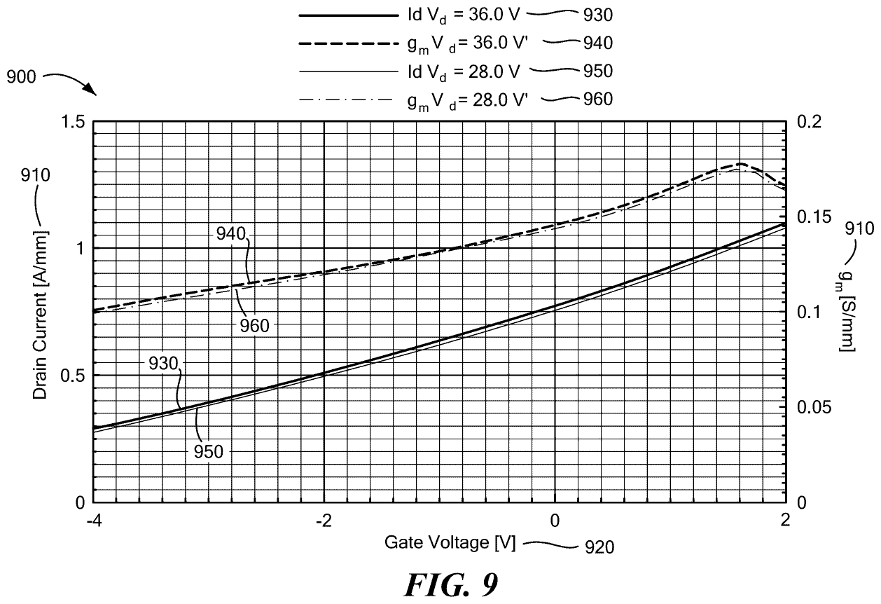

FIG. 9 is a graph 900 of drain current (A/mm) 910 and gₘ (S/mm) 912 vs. gate voltage (V) 920. In a first test with a V_{DS}=36.0 V, drain current (Id) is given in a first line 930 and gₘ in a second line 940. In a second test with a V_{DS}=28.0 V, drain current (Id) is given in a first line 950 and gₘ in a second line 960. The graph 900 illustrates transfer characteristics (I_{D}-V_{GS}) of a GaN nanosheet FET, including a single nanosheet heterostructure. The nanosheet heterostructure is 0.3 um thick and is formed from GaN doped with an n-type dopant having the doping concentration of 2.6e¹⁷ cm⁻³.

The device scheme utilized for the testing provided in relation to FIG. 9 was modeled using a technology computer aided design (TCAD) simulation tools (Sentaurus of Synopsis company). Such a device is operated at the gate bias voltage of up to 1.5 V. The drain current density of a single nanosheet FET is about 1 A/mm (+/−0.1 A/mm) at V_{DS} of 36 V which is comparable to that (about 1 A/mm) of a planar FET. Multiple nanosheet stacks may further increase the drain current density.

Disclosed herein is an enhancement mode gate all around (GAA) field effect transistor (FET) with a source and a drain positioned on either side of a length of the E-mode GAAFET, with one or more nanosheet heterostructures acting as a channel layer between the source and the drain. The device included, one or more undoped fins between which the nanosheet heterostructures, source, and drain are suspended, but none of which are in contact with the undoped fins. The current is conducted along the length of the transistor.

The disclosed GAAFET may improve electrical properties of GaN power device in a number of different ways. For instance, gate leakage current could be reduced by 30% to 70%. Further, drain current could be increased compared to those of existing GaN FETs. As disclosed above, the drain current could be increased by increasing the width of a nGaN nanosheet. Additionally, the drain current could be increased by increasing the total number of NGaN nanosheet heterostructures. The total channel resistance is reduced due to multiple channel connections in parallel. The drain current density of a single nanosheet stacks is equivalent to that of one planar GaN FET. A 450 times smaller device area is required to reach the same power density compared to planar devices. Specifically, planar: Nanosheet FETs=about 9,000 um² (+/−2 um²): about 20 um² (+/−2 um²). For comparison, the max current density in a conventional indium aluminum nitride (InAlN) InAlN/GaN high-election-mobility transistor (HEMT) is 1 A/nm, power is 4.5 W/mm, and the active HEMT area is about 100 um (+/−1 um) to 90 um (+/−1 um), with a unit device size of about 960 um (+/−1 um) to 730 um (+/−1 um).

There are a number of considerations to consider while forming the disclosed device. First, it is notably useful to ensure conformal growth of the dielectric layer (here a GaN layer doped with a p-type dopant) along GaN fins. The net doping concentration of the conformal GaN layer doped with a p-type dopant should be comparable to that of GaN layers doped with a p-type dopant that are grown on nanosheet heterostructures, which are formed from GaN layer doped with a n-type dopant. Second, the net doping concentration of nGaN nanosheet should be controlled appropriately by silane (SiH₄) flow rates as n-type dopant sources and should not be affected by the background impurity concentrations.

Compared to conventional devices, the disclosed device includes a number of detectable features. The detectable features including: (1) the height and width of the undoped GaN fins; (2) the pitch between the fins; (3) the thickness of the pGaN layers conformally deposited along the GaN fins' sidewalls; and (4) the separation distance between the lower and upper nanosheets.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

The terms “one or more” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection”.

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal, “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted that the term “selective to, “such as, for example, “a first element selective to a second element,” means that the first element can be etched and the second element can act as an etch stop.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

What is claimed is:

1. A wide-band gap material transistor device, comprising:
a substrate having first and second fins that are spaced apart and project in an orthogonal direction from a surface of the substrate;
a dielectric layer disposed over the surface of the substrate;
a channel layer provided from one or more nanosheet heterostructures disposed in the dielectric layer between the first and second fins; and
a source and a drain disposed over and in contact with the one or more nanosheet heterostructures and spaced apart from each other in a direction along a length of either the first or the second fins.

2. The wide-band gap material transistor device of claim 1, further comprising a gate, wherein in response to a non-zero voltage applied to the gate, the source and the drain conduct current through a length of the one or more nanosheet heterostructures.

3. The wide-band gap material transistor device of claim 1, wherein the dielectric layer is conformally disposed along the first and second fins.

4. The wide-band gap material transistor device of claim 3, wherein the dielectric layer has a thickness between 0.01 μm and 0.2 μm.

5. The wide-band gap material transistor device of claim 1, wherein each one of the one or more nanosheet heterostructures is fully encapsulated by the dielectric layer.

6. The wide-band gap material transistor device of claim 1, wherein the first fin has a height, a width, and a length that is different than a height, a width, and a length of the second fin.

7. The wide-band gap material transistor device of claim 1, wherein a height of either one of the first and second fins is between 0.5 μm and 3 μm, a width of either one of the first and second fins is between 0.5 μm and 1.5 μm, and a length of either one of the first and second fins is between 1 μm and 10 μm.

8. The wide-band gap material transistor device of claim 1, wherein the first fin and the second fin are spaced apart by a distance between 0.5 μm and 5 μm.

9. The wide-band gap material transistor device of claim 1, wherein a first nanosheet heterostructure has a height, a width, and a length that is different than a height, a width, and a length of a second nanosheet heterostructure.

10. The wide-band gap material transistor device of claim 1, wherein a height of the one or more nanosheet heterostructures is between 0.1 μm and 0.3 μm, a width of the one or more nanosheet heterostructures is between 0.45 μm and 0.49 μm, and a length of the one or more nanosheet heterostructures is between 1 μm and 10 μm.

11. The wide-band gap material transistor device of claim 1, wherein the dielectric layer is GaN doped with a p-type dopant.

12. The wide-band gap material transistor device of claim 1, wherein the one or more nanosheet heterostructures comprise GaN doped with an n-type dopant.

13. The wide-band gap material transistor device of claim 1, wherein the substrate is doped with a p-type dopant or an n-type dopant.

14. A method of forming a wide-band gap material transistor device, comprising:
providing a substrate;
disposing one or more buffer layers on the substrate;
disposing one or more substrate layers on the one or more buffer layers, wherein the one or more substrate layers includes first and second fins that are spaced apart and project in an orthogonal direction from a surface of the one or more substrate layers;
disposing a dielectric layer on the surface of the one or more substrate layers;
disposing a channel layer in the dielectric layer between the first and second fins, wherein the channel layer is provided from one or more nanosheet heterostructures; and
disposing a source and a drain over and in contact with the one or more nanosheet heterostructures and spaced apart from each other in a direction along a length of either of the first and the second fins.

15. The method of claim 14, further comprising disposing a gate, wherein in response to applying a non-zero voltage to the gate, the source and the drain conduct current through a length of the one or more nanosheet heterostructures.

16. The method of claim 14, wherein disposing the dielectric layer further comprising disposing the dielectric layer conformally along the first and second fins.

17. The method of claim 16, wherein disposing the dielectric layer further comprising fully encapsulating each one of the one or more nanosheet heterostructures in the dielectric layer.

18. The method of claim 16, wherein the dielectric layer is GaN doped with a p-type dopant.

19. The method of claim 14, wherein the one or more nanosheet heterostructures comprise GaN doped with an n-type dopant.

20. The method of claim 14, further comprising depositing a passivation layer on the dielectric layer, wherein the passivation layer comprises GaN doped with a p-type dopant.
